(19) United States
(12) Patent Application Publication
(10) Pub. No.: US 2015/0037922 A1
(43) Pub. Date: Feb. 5, 2015

(54) TECHNIQUES FOR IMPROVED IMPRINTING OF SOFT MATERIAL ON SUBSTRATE USING STAMP INCLUDING UNDERFILLING TO LEAVE A GAP AND PULSING STAMP

(71) Applicant: 1366 TECHNOLOGIES, INC., BEDFORD, MA (US)

(72) Inventor: Emanuel M. Sachs, Newton, MA (US)

(73) Assignee: 1366 TECHNOLOGIES, INC., BEDFORD, MA (US)

(21) Appl. No.: 14/345,675

(22) PCT Filed: Sep. 22, 2012
(86) PCT No.: PCT/US2012/056769

§ 371 Date: Mar. 19, 2014

Related U.S. Application Data
(60) Provisional application No. 61/538,489, filed on Sep. 23, 2011.

(51) Int. Cl. H01L 31/18

(52) U.S. Cl. CPC H01L 31/18
USPC 438/57

(57) ABSTRACT

A method for imparting a pattern to a flowable resist material on a substrate entails providing a resist layer so thin that during a stamp wedging process, the resist never completely fills the space between the substrate and the bottom surface of a stamp between wedge protrusions, leaving gap everywhere therebetween. A gap remains between the resist and the extended surface of the stamp. If the resist layer as deposited is somewhat thicker than the targeted amount, it will simply result in a smaller gap between resist and tool. The presence of a continuous gap assures that no pressure builds under the stamp. Thus, the force on the protrusions i determined only by the pressure above the stamp and is well controlled, resulting in well-controlled hole sizes. The gap prevents resist from being pumped entirely out of any one region, and thus prevents any regions from being uncovered of resist. The stamp can be pulsed in its contact with the substrate, repeatedly deforming the indenting protrusions. Several pulses clears away any scum layer better than does a single press, as measured by an etch test comparison of the degree to which a normal etch for a normal duration etches away substrate material. A method for imparting a pattern to a flowable resist material on a substrate entails providing a resist layer so thin that during a stamp wedging process, the resist never completely fills the space between the substrate and the bottom surface of a stamp between wedge protrusions, leaving a gap everywhere therebetween. A gap remains between the resist and the extended surface of the stamp.

### RELATED DOCUMENTS

The benefit of U.S. Provisional Application No. 61/538,489, filed Sep. 23, 2011, entitled TECHNIQUES FOR IMPROVED IMPRINTING OF SOFT MATERIAL ON SUBSTRATE USING STAMP INCLUDING UNDERFILLING TO LEAVE A GAP AND PULSING STAMP, is hereby claimed, and the entire disclosure of which is hereby incorporated fully herein, by reference.

A PCT application, designating the United States, is being filed on the same date, herewith, in the names of Emanuel M. Sachs et al., submitted by the USPTO Electronic Filing System under Attorney Docket No. 1366-0073PCT, entitled, METHODS AND APPARATI FOR HANDLING, HEATING AND COOLING A SUBSTRATE UPON WHICH A PATTERN IS MADE BY A TOOL IN HEAT FLOWABLE MATERIAL COATING, INCLUDING SUBSTRATE TRANSPORT, TOOL LAYDOWN, TOOL TENSIONING, AND TOOL RETRACTION, which PCT application claims priority to U.S. Provisional Application No. 61/538,542 of the same title, filed on Sep. 23, 2011. The PCT application is referred to herein below as the co-pending application and is hereby fully incorporated herein by reference. The priority Provisional application is also hereby fully incorporated herein by reference.

### BACKGROUND

Certain processing schemes and architecture are disclosed in Patent Cooperation Treaty Application No: PCT/US2008/002058, entitled, SOLAR CELL WITH TEXTURED SURFACES, Filed: Feb. 15, 2008, in the names of Emanuel M. Sachs and James F. Bredt and The Massachusetts Institute of Technology, designating the United States of America, the National Phase of which is U.S. patent application Ser. No. 12/526,439, issued as U.S. Pat. No. 8,257,998 on Sep. 4, 2012, and also claiming priority to two provisional U.S. applications, No. U.S. 60/901,511, filed Feb. 15, 2007, and No. U.S. 61/011,933, filed Jan. 23, 2008. All of the PCT application, the U.S. patent, patent application, and the two US provisional applications are hereby incorporated fully herein by reference. The technology disclosed in these applications is referred to herein collectively as Self Aligned Cell (SAC) technology.

Certain additional processing methods and apparatus are disclosed in Patent Cooperation Treaty Application No. PCT/US2009/002423, entitled WEDGE IMPRINT PATTERNING OF IRREGULAR SURFACE, filed Apr. 17, 2009, in the names of Benjamin F. Polito, Holly G. Gates and Emanuel M. Sachs, and the Massachusetts Institute of Technology and 1366 Industries Inc., designating the United States of America, the National Phase of which is U.S. patent application Ser. No. 12/937,810, and also claiming priority to two provisional U.S. applications, No. U.S. 61/124,608, filed Apr. 18, 2008, and No. U.S. 61/201,595, filed Dec. 12, 2008. All of the PCT application, the U.S. patent application, and the two US provisional applications are hereby incorporated fully herein by reference. The technology disclosed in the applications mentioned in this paragraph is referred to herein collectively as wedge imprint technology or wedging technology, although in some instances protrusions having shapes other than wedges may be used. The related applications are referred to below as the Wedging applications.

In brief, such wedge imprint technology includes methods. Patterned substrates with a specified texture for photovoltaic and other uses are made. As shown with reference to FIGS. 1, 2, 3, 4, and 5 and 6, the substrates are made by impressing protrusions 112 of a flexible stamp 110, upon a thin layer 202 of resist material, which covers a substrate wafer 204. The stamp tool used is of a material (typically elastomeric) that is soft enough so that the tool deforms upon contact with the substrate or wafer 204 upon which a coating of resist 202 has been previously applied. FIG. 3 shows the protrusions 112 of the stamp 110 just contacting the surface 203 of resist 202. The resist becomes soft upon heating and moves away from the locations of impression at the protrusions 112 under conditions of heat and pressure, revealing regions of the substrate adjacent to the protrusion. The resist can be heated before or after the stamp contacts the resist, or both before and after, and even while the stamp contacts the resist. The substrate is then cooled with the stamp 110 in place, the stamp is removed, as shown at FIG. 5, leaving regions 522 of the substrate exposed under holes 521, from where the resist has been moved away. The substrate is further subjected to some shaping process, typically an etching process. Exposed portions 522 of the substrate are removed by an action, such as etching, and portions of the substrate that are protected by the resist, remain, as shown in FIG. 6 at 622 (etched away) and 623 (un-etched, or less etched) respectively.

A typical substrate is silicon, and a typical resist is a wax or a mixture of waxes and resins. The stamp may be used over and over again. The protrusions of the stamp may be discrete, spaced apart, such as the pyramidal elements 112 shown. Or, they may be extended, wedge shaped elements, such as shown in the wedging applications. Or, they may be a combination thereof, or any other suitable shape that can cause the resist material to move away from the original covering condition.

Thus, a stamp is used to pattern a resist layer on a workpiece, which is then subjected to a different shaping step, to shape the workpiece. The workpiece may then be used for photovoltaic, or other uses. Textures that can be provided to the workpiece include extended grooves, discrete, spaced apart pits, and combinations thereof, as well as intermediates thereof. Platen or rotary-based techniques may be used for patterning the workpiece. Rough and irregular workpiece substrates may be accommodated by using extended stamp elements to insure that the shaped portion of the stamp contacts the surface of the workpiece. The stamp may be brought to bear upon the workpiece by any suitable means, such as translating a platen, or preferably by mounting the stamp on a flexible membrane that translates under the influence of a pressure differential across it. The flexible membrane may be part of a bladder that is inflated. Methods described in the wedging application and above are referred to herein as wedge imprinting or wedging.

In one approach to wedging, as shown schematically in FIG. 4, enough resist 402 is provided so that during the process of making an imprint, a volume of resist 402 substantially completely fills the volume 418 between the substrate 204 and the extended surface 115 of the stamp 110 between the protrusions 112 (also referred to herein as the filled volume method). (Please note that FIGS. 3 and 4 are not to the same scale.) When the stamp is removed, as shown in FIG. 5, openings 522 remain where the protrusions 112 had been.

It has been observed that the filled volume method is very sensitive to the uniformity of the thickness of the resist layer applied to the wafer. Either too little or too much resist give rise to different problems.

Turning to another matter, with one embodiment of wedging methods, the stamp is carried on a flexible membrane that is pushed down on the resist-covered substrate by pressure applied behind the membrane. The stamp can be formed integrally with a wider area membrane, or it can be a separate element fixed to a membrane. In general, the stamp is pressed once against the resist, toward the substrate, which it contacts, once, and it is then withdrawn.

A problem sometimes arises. Sometimes, a very thin film of resist can remain upon the substrate, that is, is not cleared away by a soft stamp, leaving the substrate covered albeit to a minimal extent. This so-called scum cover layer can be extremely thin, yet can still deleteriously delay the onset of, or even prevent etching.

### SUMMARY

According to one aspect of an invention hereof, the designer provides a resist layer that is thin enough so that during the wedging process, the resist never completely fills the space between the substrate and the bottom surface of the stamp between the protrusions, leaving a gap everywhere there between. That is, a gap remains between the resist and the extended surface of the stamp. If the resist layer as deposited is somewhat thicker than the targeted amount, it will simply result in a smaller gap between resist and tool. The presence of a gap assures that no pressure can build up under the tool. As a consequence, the force on the protrusions is determined only by the pressure above the stamp and is therefore well controlled, resulting in well-controlled hole sizes.

According to an aspect of another invention hereof, the stamp is pulsed in its contact with the substrate, e.g., the pressure applied to the stamp (and thus the substrate) oscillates between a higher pressure and a lower pressure, repeatedly deforming the indenting protrusions. Several pulses may, in some cases, clear away the scum layer, leaving the substrate uncovered, better than does a single press, as measured by an etch test comparison of the degree to which a normal etch for a normal duration etches away substrate material, as discussed below.

### BRIEF DESCRIPTION OF THE FIGURES OF THE DRAWING

These and other objects and aspects of inventions disclosed herein will be better understood with reference to the Figures of the Drawing, set forth above and the present discussion.

FIG. 1 shows, schematically, a stamp used for wedging (prior art);

FIG. 2 shows, schematically, the stamp of FIG. 1 and a substrate coated with resist, to be patterned by the stamp (prior art);

FIG. 3 shows, schematically, the stamp and substrate of FIG. 2, with tips of protrusions of the stamp just contacting the resist (prior art);

FIG. 4 shows schematically a stamp and a substrate, with the protrusions of the stamp deformed and pressed against the substrate, and with resist substantially filling the space between the substrate and the body of the stamp (prior art);

FIG. 5 shows, schematically, a stamp and substrate, with a patterned resist coating the substrate after wedging with the stamp (prior art);

FIG. 6 shows, schematically, a substrate after etching, with a patterned resist mask as shown in FIG. 5 (prior art);

FIG. 7 shows, schematically, a stamp and a substrate of an invention hereof, coated with resist, with the protrusions of the stamp deformed and pressed against the substrate, and with resist not filling the space between the substrate and the body of the stamp, leaving gaps therebetween, engaged in wedging, shown from a corner of the assembly;

FIG. 8 shows, schematically, the stamp and substrate of FIG. 7, in a side view of the assembly;

FIG. 9 shows, schematically, the stamp and substrate of FIG. 7, after wedging, with the components separated, revealing patterned, peaked resist;

FIG. 10A shows, schematically, a stamp and resist coated substrate before the initiation of a pulse, with the stamp protrusion tip penetrating the resist later, contacting the substrate, but un-deformed;

FIG. 10B shows, schematically, the stamp and resist coated substrate of FIG. 10A, at the initiation of a pulse, with the stamp protrusion tip penetrating the resist layer, deformed and flattened against the substrate; and

FIG. 10C shows, schematically, the stamp and resist coated substrate of FIGS. 10A and 10B, at the conclusion of a pulse, with the stamp protrusion tip penetrating the resist layer, again, un-deformed.

### DETAILED DESCRIPTION

According to one or more embodiments, a method of applying and patterning a resist is provided that is not very sensitive to the uniformity of the thickness of the resist layer applied to the substrate. According to one or more embodiments, a method of applying and patterning a resist is provided that enables determining relatively precisely how much pressure is being applied on each protrusion indenter, and also to enable relative uniformity in the pressure required so that nearly all of the protrusions fully push aside all of the resist between the protrusion and the substrate, and create a uniform size hole in the resist. Because trapped air may also give rise to locations of spuriously non-uniform pressure, and thus, irregularity in the size of the holes in the resist created, in other embodiments, a method of applying and patterning a resist is provided in which air is not trapped between the resist and the stamp tool. The disclosed method and system are reliable and reproducible.

In the present document, the item that has been referred to above as a stamp may also be called a tool. The elements of the stamp that protrude and are used to make impressions in the resist material are usually referred to as protrusions. They may also be called indenters, projections, wedges, and pyramids. The substrate upon which the resist material is provided, and then patterned, is typically referred to as a substrate. It may also be called a wafer or a workpiece. The material that is provided on the substrate may be referred to as resist, or as a flowable material, or, simply a material.

A method of imparting a pattern to a resist layer on a substrate is provided which removes enough of, and, preferably, substantially all of the resist in designated locations, so that adequate etching will take place in the regions from which the user has displaced the resist, during an etching period of acceptably short duration.

It is helpful to discuss the concept of removing the etch resist material. In general, the purpose of resist is to provide a protective coated layer to prevent etching of the substrate material where resist exists. The purpose of patterning the resist is to remove resist only from the areas of the substrate where etching is desired, leaving such areas uncovered. It has been surprisingly discovered that in some cases, even a resist layer that is too thin to be perceived by a white light microscope can still be thick enough to prevent adequate etching during a normal etching process of a normal duration.

The sufficiency of resist layer removal (or clearance/displacement from the substrate surface) can be established using an etching test. Thus, in cases in this specification where it is said that resist material is completely removed, or fully removed, or that the substrate is not covered with resist or that the stamp contacts the substrate, it is meant that the resist material is removed at least to a degree such that a normal etching operation, with normal etching chemicals, for a normal duration, achieves an acceptable amount of etching away of the underlying substrate. If it is, then it is considered that the resist material was removed from the substrate, or cleared away from the substrate, or, at that point, the stamp contacted the substrate, or similar phenomena of resist removal has occurred.

For the purposes of determining sufficiency of resist removal, etching is demonstrated on the following standard etch conditions. For example, a suitable etching chemistry is the family of mixtures of nitric, and hydrofluoric acids as is well known in the art. Other acid and additives may be added as is also well known in the art. A typical etch will be composed and an operating temperature chosen so that the etch rate of silicon lies in the range of 0.5-5.0 microns per minute. In a suitable etch test, there should be visible etching within an amount of time required to etch no more than 1 micron of silicon. For example, if an etch and temperature is used which results in an etch rate of 2 microns per minute, visible etching should take place within 30 seconds in order to deem a region not covered with resist. The occurrence of etching can be determined by several means. In many cases, bubbles of gas are formed as a product of the etch and these bubbles are visible. Another method is to stop the etch after the designated time (30 seconds in the above example), remove the resist and examine the wafer microscopically to see if etch pits have begun to form at each site that corresponded with an indenter. This test of resist removal is referred to herein in some places as an “etch test”.

There are a number of factors that affect the quality and effectiveness of the patterning process. The relevant factors are: the thickness of the resist material; the duration of contact of the protrusion to the resist material under conditions of temperature such that the resist is flowable (referred to below as the contact time); the viscosity of the resist material; the wetting angle of the resist material and the protrusion material; the proximity of the surface of the resist material to the concave corner 124 formed between the protrusion and the extended surface 115; the rate of flow of the resist material; the duration of the etching process; and the degree of resistance to the etching provided by different thicknesses of resist.

Also, as discussed generally above, in discussing the methods and systems herein, it is helpful to consider a benchmark situation, in which, when the stamp protrusion 112 is compressed to the desired degree to achieve the desired size holes 521, the entire volume 418 between the top surface of the substrate wafer 204 and the extended surface 115 of the stamp 110 is filled with resist. The amount of resist material that is sufficient to provide such a so-called benchmark thickness, as discussed below, is referred to herein as one benchmark unit of resist.

Consider the case of a filled volume method where somewhat more resist is applied than a benchmark Unit, ranging from a resist thickness of approximately 1 to (somewhat arbitrarily) approximately 1.3 (or more) benchmark Units. (The upper limit of 1.3 is chosen for illustration purposes only. It is a reasonable value to explain the issues, but is not based on rigid engineering analysis.) If this too-thick resist is applied uniformly, the holes will be smaller than desired. If this too-thick resist is applied in local areas, the holes in those areas will be smaller than in other areas and there will be variation in hole size across the wafer. At a certain amount of excess resist thickness, no holes at all will be created. The resist material does not flow to even out, from regions that have relatively more material, to regions that have relatively less material, because at the temperatures involved, the material is too viscous to travel the required distances, which are on the order of centimeters, during the required time, on the order of seconds or tenths of seconds, especially given that the height of the channel through which the material must flow is approximately 10 microns.

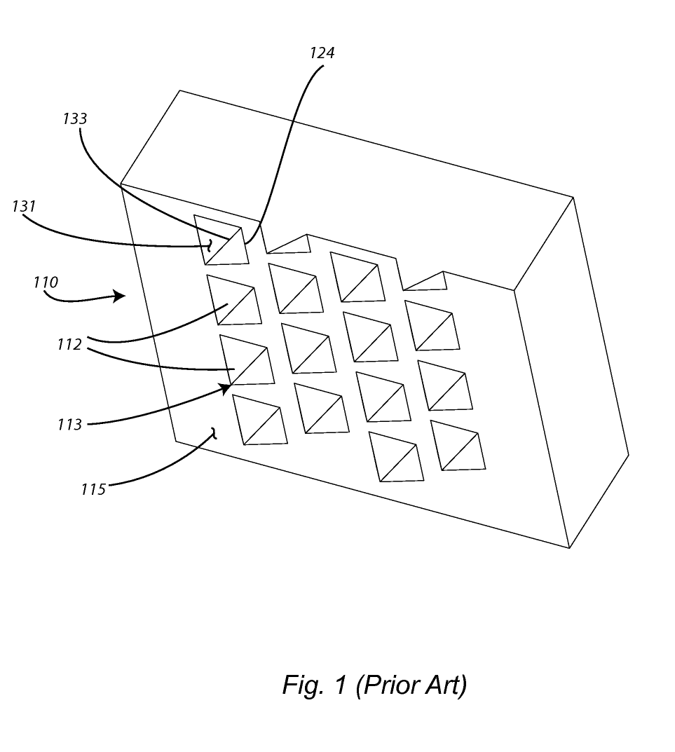

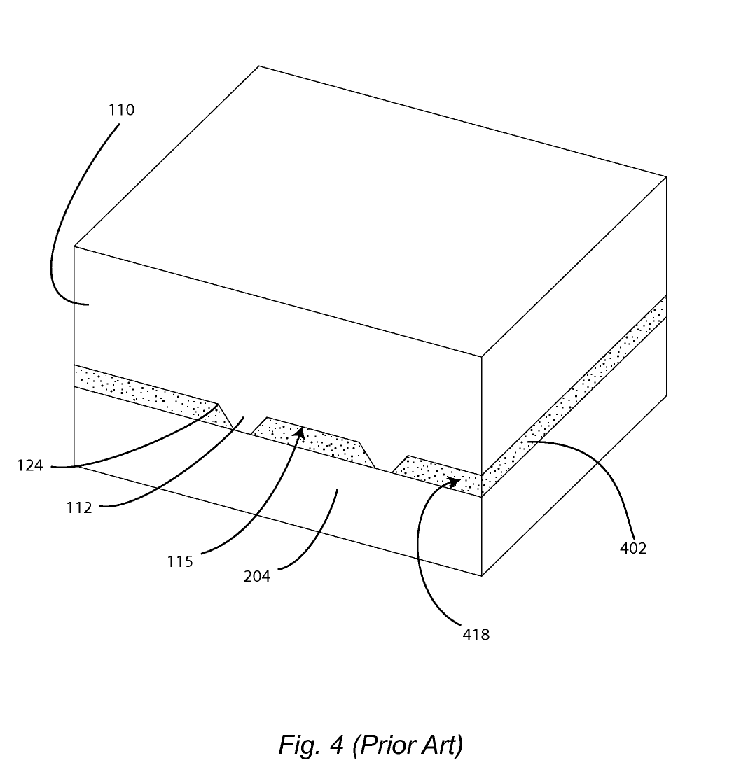

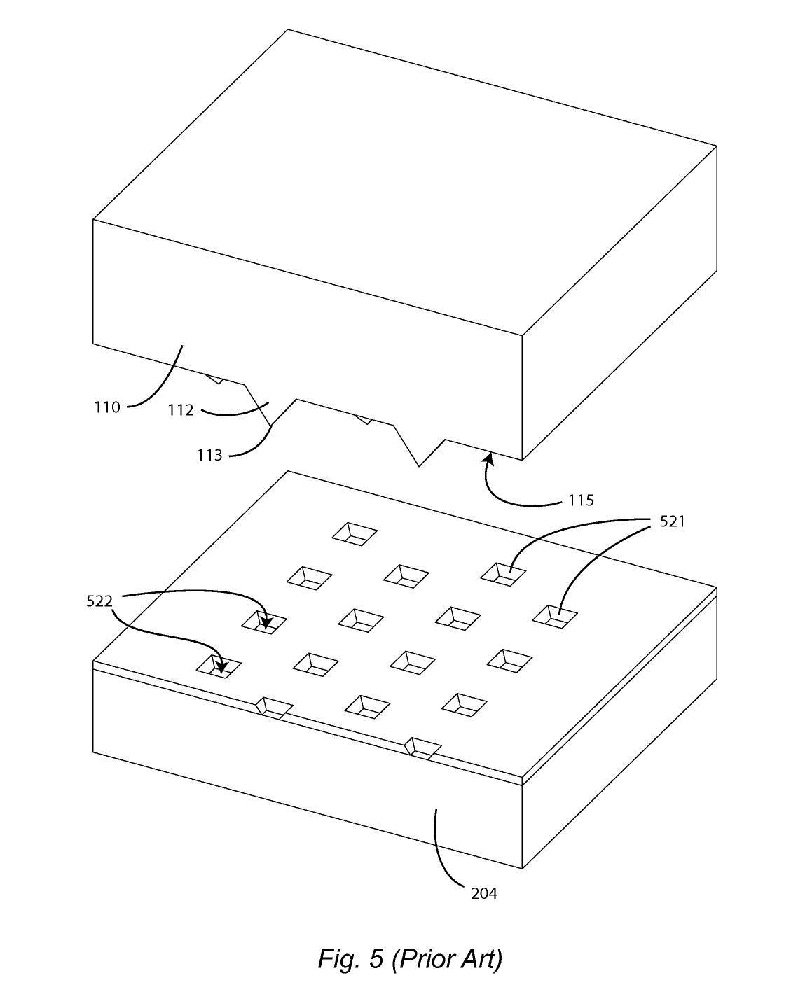

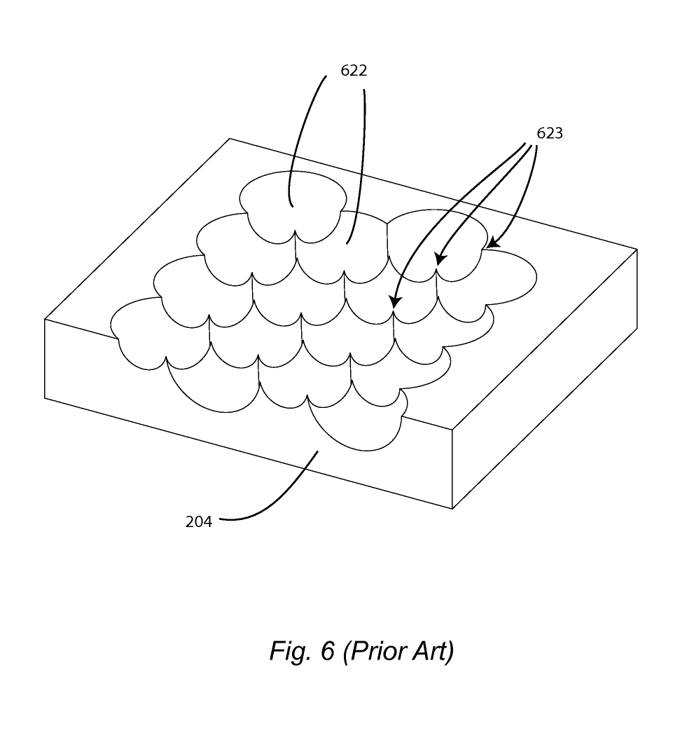

It is also helpful to consider an attempt to achieve a filled volume, in a case where somewhat less resist is applied than a benchmark Unit, for instance from a resist thickness of approximately 1 to (again somewhat arbitrarily) approximately 0.8 benchmark units. In such a case, there is a risk that significant regions may be drained of resist due to a high capillary suction created at the concave corners 124 (FIGS. 1 and 4), where the protrusion 112 intersects with the extended surface 115 of the stamp 110. Resist material that is in this region is attracted and retained by capillary suction. This high capillary suction results in adjacent regions that already have thin resist to further drain, as explained below. (The lower value 0.8 units is chosen for illustration purposes only. It is a reasonable value to explain the issues, but is not based on rigid engineering analysis.)

For example, consider a case where a benchmark unit amount of resist is applied in most locations across the wafer, but too little is applied in patches, e.g., of several cm in dimension. In this case, throughout the region with resist thickness of a benchmark unit, the resist fills the concave corners 124, resulting in high capillary suction. Such a region would therefore be relatively difficult to drain of resist. However, in the patches with less than a benchmark unit thickness of resist, the resist does not reach the concave corners 124, and so, such a region is relatively easy to drain of resist, in part because there is no excess capillary suction resisting draining.

A significant problem comes at a boundary between a first region filled to a degree that the resist reaches up the face 131 of the protrusion, and reaches up to the concave corner 124, but does not entirely fill up the volume between a pair, or a group of protrusions, and a second region filled to a degree less than this. At these boundaries, the resist is drawn from the least filled regions toward those that are filled up to and beyond the corner 124. A portion of the flat extended surface 115 of the stamp is, for a time free of resist. But, the capillary suction at the concave corner 124 continues to act upon the continuous volume of resist adjacent thereto, which is hydraulically communicating with resist from adjacent locations, closer to the substrate. This causes a flow from the source of resist, near the substrate, along the faces 131 of the protrusions and along the extended surface 115 of the stamp. Eventually, the volume of space near this capillary suction may become filled. But, it becomes filled with resist material that has flowed from adjacent regions, which are not full, and, in fact, where portions of the substrate can become uncovered.

Thus, partially filled regions tend toward an unstable situation where the least filled regions continue to drain of resist, until the other regions are completely filled, or until the least filled regions are completely empty. In either case, some regions of the substrate become uncovered, or nearly so, with only a very thin layer remaining.

If it were possible to provide the benchmark unit amount of resist material everywhere over the surface of the substrate, the uncovering problem would not occur. But it is not typically possible using reasonable effort. To further understand the problem, and why it is difficult to provide a benchmark unit thickness of resist material, it is helpful to consider what would be the benchmark unit of resist material, for a perfectly controlled process.

The benchmark unit of resist can be determined by calculating backwards from a desired resulting hole size in the substrate after etching. Knowing this size, and the duration of etching that would be best for a process situation, the designer can determine an optimal size for the openings in the resist upon the substrate.

This optimal size is achieved by the surface area and perimeter of the deformed stamp protrusion that contacts the substrate. Thus, the cross-sectional area of such a shape, and also the shape and extent of the perimeter can be determined in advance. As used herein, the term areal extent will be used to mean either the shape of the area or the shape of the perimeter, or both, of the portion of the compressed protrusion that is brought into intimate contact with the substrate. This is helpful, because force balance between the applied pressure and the contact force of the indenters most closely determines the cross sectional area of the indenters. However, certain aspects of the subsequent etching process are also closely related to the extent of the openings in the resist.

Taking a four sided pyramid as an example, it may be that the desired opening size is achieved by deforming the pyramid so that approximately one-third at the tip, of its full extension is squashed down, such that the hole is defined by the perimeter and area of the cross-section of the pyramid at one third the distance from its tip, which is also equal to two thirds the distance from its base. The benchmark unit depth of the resist could, theoretically be equal to two-thirds the full extension length of the protrusion. Resist to that benchmark depth would fully fill up the volume 418 between the extended surface 115 of the stamp from which the protrusions extend, and the substrate, when the stamp is deformed such that one third of its tip is squashed flat. That would constitute a benchmark unit for a filled volume method. The surface 115 of the stamp from which the protrusions extend is referred to herein as the stamp extended surface. For a more concrete example, using a compression of slightly less than ⅓, consider a typical case where the stamp consists of a hexagonal array of pyramidal protrusions with spacing between protrusions of 20 microns, a pyramid base of 14 microns and a pyramid height of 9.9 microns. To create holes in the resist that are 4 microns on a side, the tips of the pyramids must be displaced toward the base by approximately 2.8 microns. The amount of resist required to fill the space between the extended surface of the tool and the wafer would be a layer of thickness approximately 7.1 microns. Thus, a Benchmark Unit depth in this particular example would be 7.1 microns. It should be noted that this Benchmark Unit of resist is not the amount of resist deposited on a substrate, which would then be contacted and deformed by a tool, because one must take into account the volume that will be taken up by the intruding protrusions. Resist to a somewhat lesser thickness must be deposited. Rather, the Benchmark Unit depth is the depth at which the resist material would exist with the tool in place, and the protrusion tips deformed into contact with the substrate the required degree to achieve openings of the desired size, having displaced some material laterally, thereby increasing its depth at regions adjacent the indenters.

But, if, as explained above, only slightly less resist than this benchmark unit amount were to be provided, the problems of uncovering substrate can occur. Uncovering can occur over regions as large as tens of pitches of protrusions.

Another problem with attempting to fill the volume, even if a benchmark unit amount of resist material were to be provided, is that if air is trapped between the stamp 110 and the resist, it is very difficult for it to find a path to escape. Further if there is trapped air, that can lead to a situation where the instability described above, where resist material from one region flows to fill regions (such as of trapped air) where there is no resist, thereby possibly leading to uncovering of the regions from which the resist has flowed.

Before discussing inventions hereof that address these problems of filling, it is helpful to consider the motion of a flexible indenter relative to the substrate. The protrusion is compressed by the application of increasing pressure to the stamp. The protrusion side walls roll down onto the substrate. This rolling motion pushes the resist ahead of it, while leaving an ample path for escape of the resist from the space between the descending protrusion and the substrate. By rolling, it is meant on action where there is no slippage of the protrusion on the substrate. A contrast can be drawn to what can happen if an indenter with a flat tip is used. For example, consider an indenter which is the frustum of a right circular cylinder. In such a case, a small amount of resist can be trapped under the indenter and prevented from being expelled by a ring of contact and sealing between the perimeter of the indenter and the substrate.

### Providing a Gap

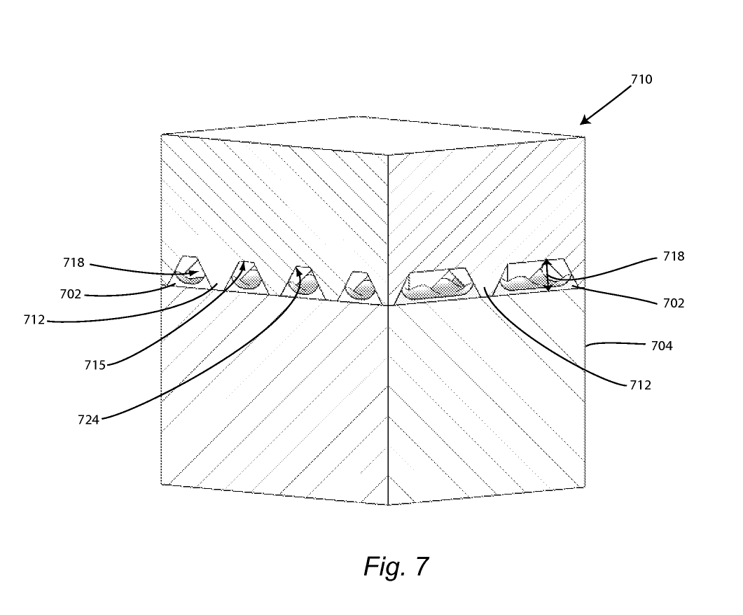

The problems discussed above in connection with providing a filling, benchmark amount of resist can be avoided with an advantageous method of an invention hereof, in which the resist thickness is selected to be less than one benchmark unit to provide a gap between the stamp and the resist at the stamp's greatest degree of compression during the stamping process. This is exemplified in a wedging process as shown with reference to FIGS. 7, 8, and 9. In general, as discussed above, one problem occurs when an operator tries to provide a filling amount of resist, but provides too little. This causes uncovering of some substrate regions. The present inventor has discovered the surprising and unexpected situation, that beneficial results are obtained if a method is used where even less resist material is used than the amount that causes the capillary suction problem discussed above in connection with providing too little material to fill the volume. This newly disclosed technique is referred to herein as a gap method, or gap mode.

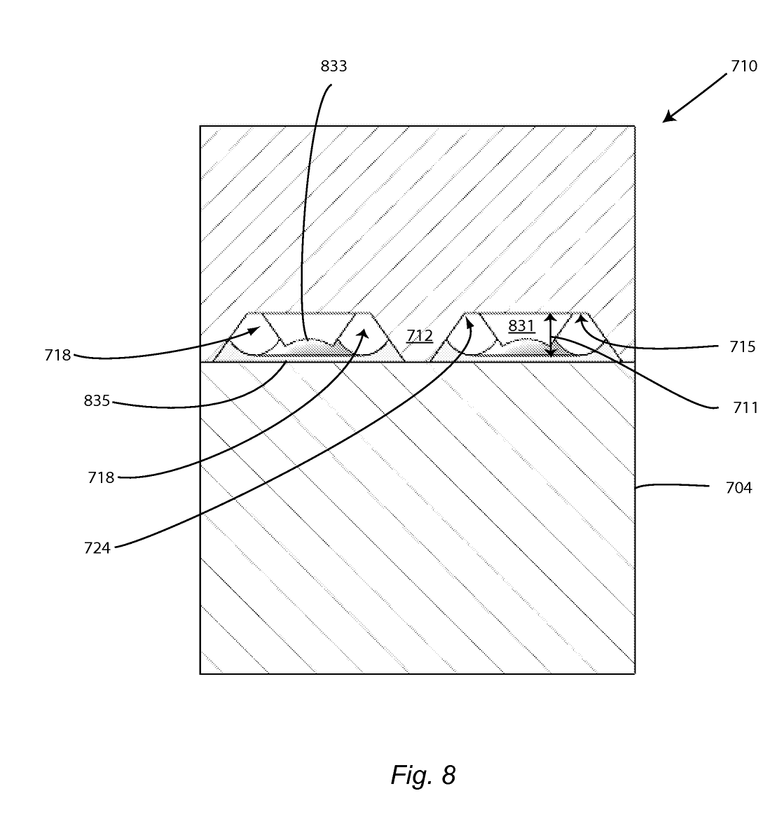

FIGS. 7 and 8 show a stamp 710, resist 702 and substrate 704 during a patterning process, with FIG. 7 showing a view from a corner of an assembly, and FIG. 8 showing the same assembly from a side. According to this method, the designer provides a resist layer 702 that is so thin that during the wedging process, the resist generally does not, at any location completely fill the space 718 between the substrate 704 and the bottom extended surface 715 of the stamp between the protrusions 712, leaving a gap therebetween. But, resist does initially and, at all times, cover the entire surface of the substrate. That is, a gap remains between the resist and the extended surface of the stamp at all times during the wedging operation.

A proper thickness of resist material to establish a gap is much less than a benchmark Unit of thickness as discussed above to fully fill the volume. In the same benchmark Units used in the discussion above, a target resist thickness for a method leaving a gap would be between approximately 0.1 and approximately 0.7 benchmark (fully filling) Units and more preferably between approximately 0.2 and approximately 0.4 benchmark Units. (As with the Benchmark unit, this is a measure of the thickness of the resist with the protrusions in place and deformed.) A primary virtue of a gap maintaining method is that it tolerates deviations in the amount of resist around this target, both in excess of and less than the target.

A gap-maintaining method tolerates resist that is deposited thicker than the target, up to approximately 0.7 benchmark units. For example, if the target thickness is 0.3 benchmark units, the resist may be locally as thick as 0.7 benchmark units without detrimental effect. This is because even at this depth, the resist is far enough away from the concave corner 124 (FIG. 1), 724 (FIG. 7), so that the resist is unlikely to climb up along the protrusion faces 131 (FIG. 1), 831 (FIG. 8), as far as the concave corners 124, 724. (It is, in some cases, more useful to refer to these items with reference to FIG. 1, which shows them in a three-dimensional view of the stamp only, and sometimes more clear to refer to the items with reference to FIG. 7, which shows them in a corner view and FIG. 8, a side view). Thus, a situation with a local high capillary suction, which drains resist from other areas, discussed above in connection with a method that attempts to fill the volume, is not created. All that happens is that the gap is somewhat thinner in some regions, which does not present any problems.

A gap-maintaining method also tolerates a volume of resist that is thinner than the target. For example, if the target thickness were to be 0.3 benchmark Unit, the resist may be locally as thin as approximately 0.1 benchmark Unit, while still retaining enough resist thickness between protrusions to resist etching. It should be noted that in practice of a properly functioning gap-maintaining method, some very local migration of resist toward the protrusions does take place while portions 833 of the resist climbs part way up the faces 131 (FIG. 1), 831 (FIG. 8) of the protrusion 112 (FIG. 1), 712 (FIG. 8). This results in some thinning of the resist in the regions 835 between protrusions 112, 712. Any such thinning should be minimized, by minimizing the time and temperature of the patterning step. However, the climbing resist 833 does not reach the concave corners 124, 724 and so, the capillary suction instability described in reference to an under-filled method that attempts to fill the volume, does not take place.

Returning to FIG. 7, the stamp has been forced downward against the resist-coated substrate by pressure applied behind it. As a result, the tips 713 of the pyramidal protrusions 712 on the stamp are flattened against the substrate 704. The size (perimeter and surface area) and shape of the created flat area defines the size and shape of the opening 921 formed in the resist layer 702 at the substrate surface. The size of the hole does not depend on the thickness of the resist, so long as it is thick enough to prevent etching, but not so thick as to result in the problems of filling more than the filled method, discussed above. The amount of resist material, the elasticity of the protrusions 712 and the force applied to the stamp 710 are all balanced so that a gap 711 always remains between the surface of the resist material 702 and the extended surface 715 of the stamp 710 between the protrusions 712. Typical elastic modulus for the stamp is between about 0.5 MPa and about 35 MPa, with a preferred range of between about 2 MPa and about 15 MPa.

The presence of a gap 711 also assures that no pressure can build up under the tool. As a consequence, the force on the protrusions is determined only by the pressure above the stamp and is therefore well controlled, resulting in well-controlled hole sizes. The force of compressing the protrusion is balanced at full compression by the force from the pressure above the tool.

A key challenge is understood with reference to FIG. 8. This challenge was mentioned briefly above.

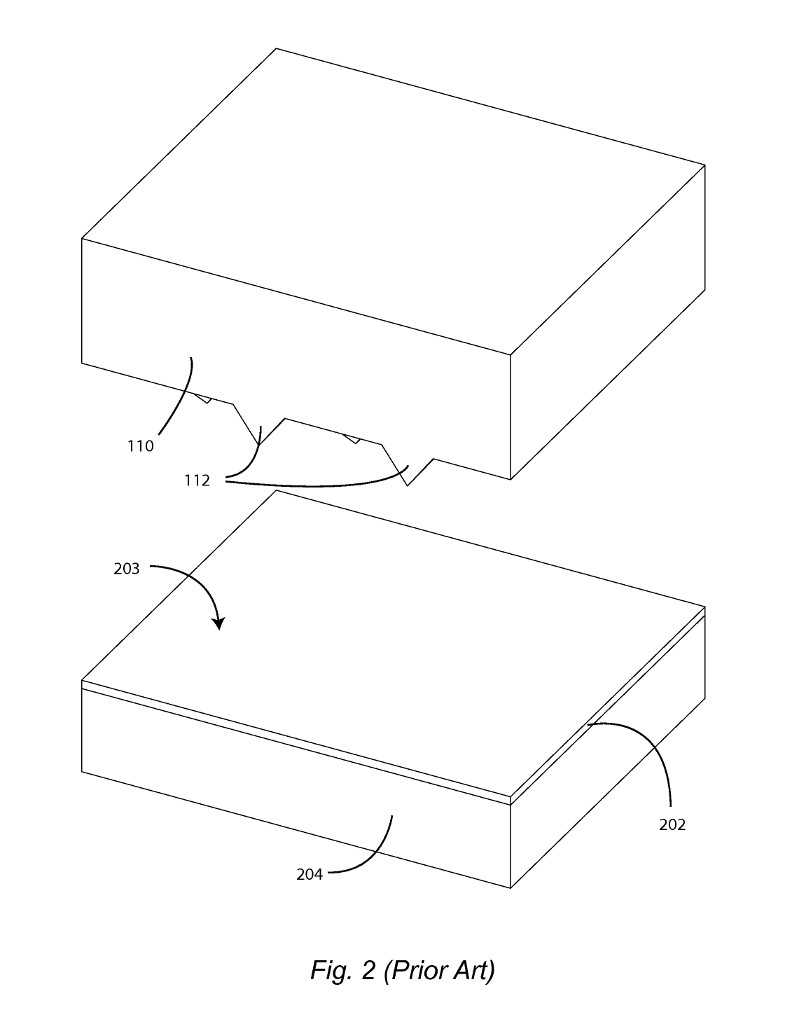

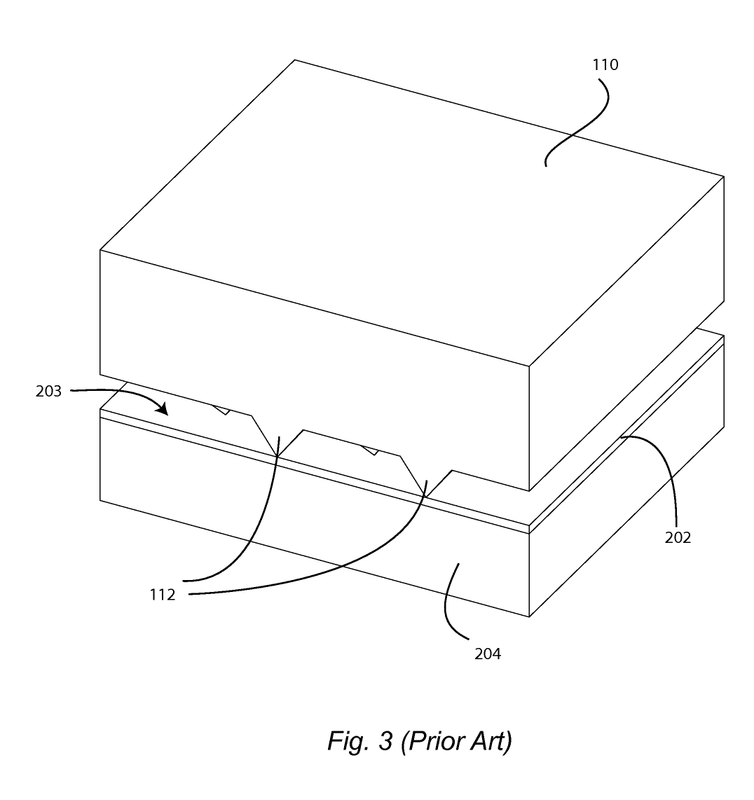

Although the resist layer starts out with a planar surface when applied to the substrate, such as shown at 203 in FIG. 2, after wedging, the top surface of the resist (ignoring the holes) is no longer planar. The resist 833 has migrated toward the protruding portions 712 of the stamp 710 that contact the resist, due to the capillary attraction along the face 831 of the protrusion 712. This migration begins to happen quickly. If the capillary action works for long enough time so that the resist material flows upward too high, additional problems can arise. This causes the resist 833 to be highest immediately adjacent to wedging stamp, forming peaks there.

Resist that has migrated up along a face 831 has migrated toward it from other regions 835. This can leave the regions from which the material has migrated, with too little or even no resist, resulting in an inability to effectively resist etching. Such an uncovered region (none are shown in these figures) can arise at an undesired location, leaving that region exposed to etching. Typically, with such a situation of too little resist, the extent of the uncovered region will be relatively small, for instance, over a distance of only a few protrusion pitches away from the protrusion(s) that have experienced the inflow migration. As a comparison, with an under-filled instance of a method that attempts to fill the space, as discussed above, the uncovered region can extend a distance of tens or hundreds of protrusion pitches. (The problem encountered when maintaining a gap differs markedly from that discussed above when filling the space, because the level of resist is so low when a gap is maintained, that no resist ever reaches the concave corner 724, and thus, the added capillary suction of a concave corner does not arise.)

However, as discussed above, despite this problem with a gap method suffering from too little resist material, there is a range of resist thickness above and below a perfect (gap-leaving) amount, which can be tolerated, without uncovering any substrate. Rather than simply preventing complete uncovering, what is important is that the amount of resist material remaining be sufficient so that after the wedging process, in the locations where it is desired that there be no etching of the substrate, enough resist material remains so that etching does not occur during the normal etching process.

It is important that the gap between the tool and the resist be consistent over the entire surface of the wafer, within the range of tolerance as discussed above. Above, it is discussed that the resist be filled at between about 0.1 and about 0.7 Benchmark units. This means that the thickness of the gap will be, correspondingly, between about 0.9 and about 0.3 Benchmark Units.

Returning to FIG. 8, some degree of control of the amount of migration of the resist 833 toward and upon the protrusions can be had by controlling the wetting angle of the resist against the stamp. This is an aspect of an invention hereof. Thus, it is desirable to have the wetting angle of the resist to the stamp be as high as possible (as non-wetting as possible), and in this way, to restrict the capillary rise of the resist up the side of the protrusion. In FIG. 8, the wetting angle is shown as approximately 90°. If the wetting angle is smaller (that is if the wetting is better), the resist will rise higher up the face 831 of the protrusion 712 of the stamp 710, which is pyramidal in the example shown.

However, there is only a limited amount of control possible in this regard because the stamp and resist materials, based on satisfying many considerations and many suitable combinations, display moderate wetting behavior. That is, any suitable combination of resist material and stamp may be found to be fairly wetting, thereby making it difficult to restrict the rise of resist material up the face of the protrusion by adjusting wetting angle alone. Further, such wetting angles may change over time as the stamp wears. For instance, the chemical composition of the surface of the stamp may change over time, due to interaction with the resist from prior runs. Additionally, scratches and other mechanical irregularities of the surface, which may arise from wear, can also affect the wetting angle, generally lowering it.

Thus, in addition to controlling the process by selecting the wetting angle of the materials, other aspects should be controlled. It is an aspect of an invention hereof to accurately control the rheology of the resist during wedging. Another aspect of an invention hereof is to control and generally minimize the amount of time that the resist is in the flowable stage. The resist must be flowable enough to allow the protrusions of the tool to displace the resist under them and to make contact with the wafer under it to sufficiently remove the resist at the protrusion to a degree so that etching does occur during a normal etching operation of a normal duration. Conversely, the resist should not be so flowable that it flows excessively away from the regions between the protrusions to the regions immediately adjacent the protrusions and up along the protrusions, because this might result in uncovered regions with too little resist to block the etchant during a normal etching duration. Control of the duration of the contact so that the extent of migration of the resist is in this relatively narrow range is part of the inventions. This extent of migration is understood to be a function of the contact time, which is the duration that the stamp contacts the hot resist while the resist is flowable. Relatively speaking regarding process tolerances, the shorter the contact time in which the process can be performed the resist can have a somewhat more flowable state. Roughly speaking, given contact times of about 1 to about 10 seconds, it has been found that the resist viscosity can be in the range of about 5,000 to about 500,000 centipoise. The range of about 20,000 to about 200,000 cps is preferred. (In some cases, it is possible for the contact time to be even as short as 0.5 seconds. A preferred range is between about 1 and about 5 seconds.)

In general, primary control is based on viscosity and the contact time. The designer tries to adjust the viscosity, such that during the contact time, the resist does not have the chance to travel far enough up along the protrusions to uncover, or unacceptably diminish regions of the substrate. Controlling the wetting angle, such as through material selection and stamp wear, replacement and surface treatment, provides another control variable, but of lesser effect. The wetting angle influences the maximum travel distance of the liquid along the stamp, as well as the rate of such travel.

It will be understood that throughout this specification, the term viscosity is used to characterize the rheology of the resist. The resist may exhibit Newtonian, or non-newtonian behavior. Further, the resist may have a yield stress.

It is particularly advantageous to use a wax as at least one component of the resist material. Waxes encompass a broad range of polymers that have the general properties of having a relatively low melting point and having melts with very low viscosities. Waxes are advantageous because the low melting points allows the wedging process to be performed at temperatures typically below 100° C. This in turn reduces the chemical interactions between the resist and the stamp and opens up options for choices of materials of the stamp and other aspects of the wedging equipment. In addition, the relatively low temperature possibility means that the temperature cycling required for wedging can be rapid and not incur as large an energy cost as a process at a higher temperature. The low viscosity of wax melts is advantageous because the wedging can be performed with a soft tool—a stamp made of rubber. Further, the low viscosity allows the wedging to be performed rapidly, yet with only low pressures applied to the stamp (and therefore to the wafer). (It should again be reiterated that viscosities of even as high as 200,000 or 500,000 are considered to be relatively low, in this context, because this compares to viscosities of about 10 million for polymer melts.)

Waxes are processed by taking advantage of the low viscosity state of wax melts. For example, wax is used as so-called solid ink in some ink-jet printing devices. However, the very attractiveness of the low viscosity melts associated with waxes means that it is all too easy to be in a regime where the resist is too fluid and results in an insufficient resist thickness in the region between the protrusions after wedging to resist etching. An aspect of an invention hereof is to recognize that waxes and mixtures containing waxes can be controllably used in the desired range of viscosities.

To use wax and to maintain it in the desired viscosity range during the contact duration, several considerations should be observed. The wax-based resist should be able to tolerate at least about a 2° C. and preferably about a 5° C. temperature range over which the viscosity is in the desired range. This excludes some common waxes. For example pure paraffin wax moves too abruptly from a soft solid state to a low viscosity (typically less than 100 cps) melt state. It is particularly advantageous for the wax-based resist to be a mixture of two or more different components, each with different rheological properties as a function of temperature. Such a combination composition, for example of waxes, resins and rosins, provides a relatively broad temperature range over which the desired range of viscosities can be met. The processing temperature during the contact time should be held below the nominal melting temperature. It is also important to maintain very accurate control of the temperature across the wafer during the contact time, with preferred control of +/−1° C.

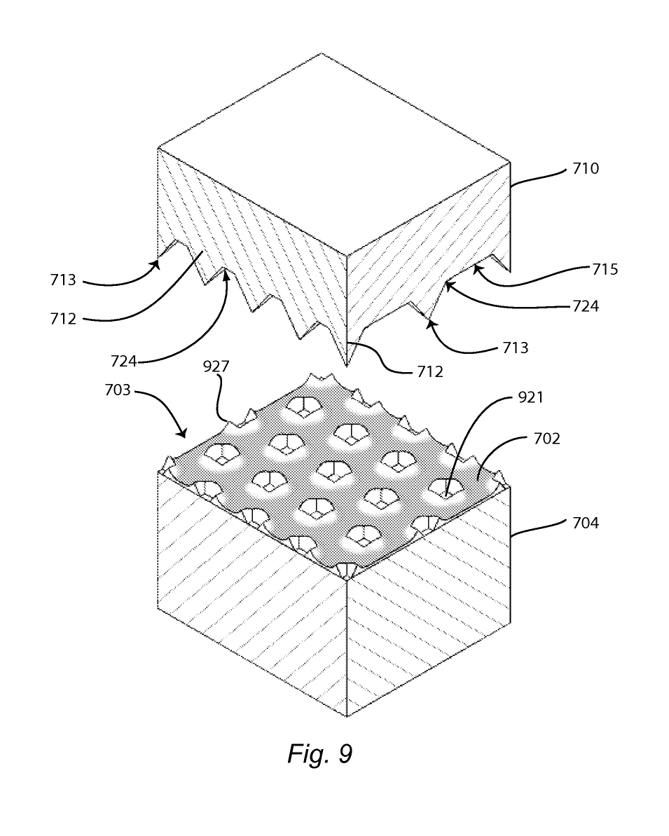

FIG. 9 shows the stamp 710 withdrawn from the substrate 704. Note that the pyramidal protrusions 712 have returned to their original shapes with sharp points 713. FIG. 9 also shows the patterned resist layer 702 with substantially square openings 921 through the resist and peaked borders around the openings. In a subsequent step, the substrate 704 will be exposed to etchant, which will etch the exposed silicon. While the patterned holes 921 are shown as substantially square, the deformation of the projection pyramid actually results in slight lobes (not shown), at the corners. FIG. 9 also shows that adjacent the holes 921, the surface 702 of the resist layer 703 has raised portions 927, where the resist 833 (FIG. 8) had been drawn up along the faces 831 of the protrusions 712. The resist solidified in this raised configuration.

While the above description has been in the context of stamps that have pyramidal protrusions with four faces, other protrusion shapes are possible, including cones and rounded nose, circular cylindrical protrusions—both of which would result in round holes in the resist. Another advantageous shape for the protruding feature is that created by the revolution of a parabola. In such a shape, the indenter has its largest diameter at the base where it meets the extended surface of the stamp and then continuously decreases in diameter toward the tip of the indenter. The tip is rounded to provide for the expulsion of resist as the pressure behind the stamp is increased and the protrusion is compressed against the substrate. Further the ever widening body of the protrusion (moving from tip to base), provides for lateral stability and minimizes the chance of the indenter buckling while it is being compressed.

During the imprinting operation, the resist-coated substrate may be placed on a temperature-controlled chuck and it might be held against this chuck by the application of vacuum. The chuck temperature can be controlled by the passage of heated and cooled fluids through it. A patterning cycle would then consist of the resist-coated substrate being heated on the chuck and the stamp being forced against the chuck, typically by the application of pressure behind the stamp. The substrate and resist would then be cooled with the stamp still in place. Finally, the stamp would be removed from the resist-coated substrate, typically by peeling the flexible stamp. The contact time is the duration that the stamp is in contact with the resist and substrate. A total cycle may be as short as a few seconds.

The size of the holes in the resist is advantageously determined by the amount of deformation of the protrusions 712. This in turn, is determined by the force on each individual protrusion. The force can be controlled by applying pressure to the back of the stamp. Because the stamp is flexible, this results in good control of the average force over a useful local region of protrusions, even when the substrate is not completely flat.

In general, the force on each protrusion will be approximately equal over an area that spans, in each lateral direction, a distance equal to several thicknesses of the stamp. It can be seen that a virtue of a method that maintains a gap, where there is no hydrostatic pressure built up in the fluid, is that the forces on the stamp can be regularly determined by considering only the pressure applied to the stamp, and the spring force generated by compression of the protrusions by the known amount. Without any hydrostatic fluid pressure, these forces (pressure and spring) balance at the point of maximum deformation of the protrusions. Thus, for irregularities in the thickness of the resist material, or the flatness of the substrate or a combination of both, that are as large or larger in lateral extent than several thicknesses of the stamp, the force on each protrusion within that area of irregularity will be approximately equal, and will also be approximately equal to the force on each protrusion in as sufficiently large regions outside the area of irregularity in question. The force upon protrusions in the vicinity of transitions from the region of irregularity to adjacent regions will not be as uniform as in the larger regions just discussed. As an example, a stamp may have an overall thickness of approximately 0.3 mm, with the protrusion being approximately 0.01 mm (10 microns) (typically within a range of between about 2 and about 20 microns). Such a stamp will experience a uniform force upon the protrusions over a region that spans at least approximately 0.7 mm in each of two orthogonal directions. For irregularities smaller than that expanse, the force upon protrusions at such an irregularity will not be particularly close to the force on protrusions in other, more uniform regions. The stamp can have an overall thickness ranging between about 0.05 mm and about 1 mm, with a preferred range being between about 0.1 to about 0.5 mm. Thinner stamps are better able to conform to surface irregularities and roughness in the substrate. The combination of a thin and therefore very flexible stamp, together with hydrostatic pressure applied to the back of the stamp, provides a system which can create a high fidelity pattern on rough and undulating surfaces.

The combination of the applied force and the elasticity or stiffness of each protrusion determines the size of the contact area between the deformed protrusion 712 and the substrate 704. This, in turn, determines the size of the opening 921 in the resist. Because there is always a gap 711 between the resist 702 and the extended surface 715 of the stamp between the protrusions 712, air can pass freely in this gap and escape out the sides of the stamp. As a result, there is no build up of pressure in the air and therefore, the net force on the aggregation of the protrusions is determined only by the pressure applied at the back of the stamp.

To guarantee that air can escape from between the stamp and the resist/substrate, sealing of the stamp to the edge of the substrate should be prevented.

There are many advantages of the methods disclosed herein providing a gap between the resist layer and the stamp surface, as compared to methods that attempt to fill the volume.

The absolute thickness of the resist layer 702 is important but not critical, as long as it is within the operational limits of not too much, and of not too little resist, as discussed above.

The amount of resist to be provided can be determined by working backwards from the desired resulting hole size in the substrate after etching. Knowing this size, and the duration of etching that would be best for a process situation, the designer can determine an optimal size for the openings in the resist upon the substrate. This optimal size is achieved by the areal extent of the deformed stamp protrusion that contacts the substrate (with contact defined by an etching test). For instance, taking a four sided pyramid as an example, it may be that the desired opening is achieved by deforming the pyramid so that one-third at the tip, of its full extension is squashed down, such that the hole is defined by the perimeter of the cross-section of the pyramid at one third the distance from its tip, two thirds the distance from its base. The depth of the resist must be significantly less than two-thirds the full extension length of the protrusion. Otherwise, it would fully fill up the volume between the main body of the stamp and the substrate, when the stamp is deformed such that one third of its tip is squashed flat. That would entail all of the problems discussed above with methods that attempt to fill the entire volume. Thus, for a method that maintains a gap, there must be a degree of under-filling sufficient to leave a gap over substantially the entire surface of the resist when the protrusion is deformed to the degree necessary to achieve the desired hole size for the duration of the stamp contact time. As discussed above, this degree of filling is somewhere between about 0.1 and 0.7 benchmark Units that would fill the volume. Present process control capabilities certainly enable avoiding a degree of fill that would create a problem, of above 0.7 benchmark Units.

To be more precise, continuing with the example set forth above in connection with a method that attempts to fill the volume, as a measure of a Benchmark Unit, consider a typical case where the stamp consists of a hexagonal array of pyramidal protrusions with a spacing between protrusions of 20 microns, a pyramid base of 14 microns and a pyramid height of 9.9 microns. With a fully filled volume, to create holes in the resist that are 4 microns on a side, the tips of the pyramids must be displaced toward the base by approximately 2.8 microns. The amount of resist required to fill the space between the extended surface of the tool and the wafer would be a layer of thickness approximately 7.1 microns (when the indenters are deformed). Thus, a Benchmark Unit depth would be 7.1 microns. Therefore, for a method of an invention hereof that maintains a gap, the degree of filling is between 0.1 and 0.7 benchmark units, translates to a depth of resist between 0.7 and 5 microns.

Protrusions can be separated by between about 5 microns and about 100 microns, or even more, depending on the design of the end product. Their height can be between about 2 microns to about 100 microns, or more, also with regard to the design of the end product. Typically, smaller indenters will be spaced more closely together, although this is not necessarily so.

To summarize the recent discussion, the proper amount of resist material to provide for a method that maintains a gap, is that amount such that: when the stamp is pressed down to the substrate, and is deformed to a degree such that the proper amount of areal extent of the deformed protrusion contacts the substrate, such that the proper size hole in the resist material will be formed after it solidifies and the stamp is removed, a gap remains, during the entire contact time, between the surface of the resist and the extended surface of the stamp. Further, the entire area of the substrate desirably remains covered during the contact time. Further, the resist is present in all of the resist covered regions to a depth that resists etching, based on an etch test. A useful guide, although not an absolute requirement, is to provide between about 0.1 and about 0.7 benchmark Units of resist material that would fill the volume, preferably between about 0.2 and about 0.4 benchmark Units.

The size of the holes 921 in the resist layer 702 is controlled accurately because only the force on the protrusions counteracts the pressure applied to the top of the stamp. That is, no hydrostatic pressure develops in the resist, because the resist is not in contact with the majority of the stamp, for instance at the extended surface 715 between the protrusions.

There is a continuous channel for air to escape from between the resist-coated substrate and the stamp, to the environment surrounding the stamp.

There is a smaller contact area between the resist and the stamp than there would be in a method that attempts to fill the volume, making peeling (withdrawal of the stamp away from the indenting position) easier. There is also a path for air to enter the space between the stamp and the resist layer as the stamp is peeled, thereby avoiding the creation of suction.

Methods of inventions hereof that maintain a gap are conducted at a relatively low temperature. This relatively low temperature is used so that the viscosity of the resist is high enough to prevent excessive resist migration. Thus, the temperatures to which the stamp is exposed are limited, thereby providing for long stamp life and allowing for a large range of materials to be used for the stamp.

Further, the magnitude of the temperature swing that must be imposed on the substrate is limited, allowing for flexibility in choice of materials of construction and acceptably low time and energy required to swing the temperature up and down.

Thus, operating a wedging process with a persistent gap between the resist and the body of the stamp solves many problems, and provides reproducible, economical results.

It should be noted that the majority of the benefits of leaving a gap are preserved even when some areas over a wafer substrate are filled with resist. In other words, the benefits arise even if a continuous gap does not exist over the entire surface of the resist. For example, consider a 156×156 mm silicon wafer substrate where 10% of the resist has been deposited at too large a thickness to leave a gap—that is a thickness that results in filled condition. For instance, these thicker areas of resist might occur in spots of 1-5 mm diameter distributed across the wafer. These spots will result in filled condition while the remainder of the wafer can remain with a gap. Moreover the hole size in the spots which are filled will be the same as or very close to the hole size in the gap region. This is because the size of each filled region is small enough that the resist can flow laterally until the resist itself is not exerting significant pressure on the stamp and the equilibrium of the stamp is determined by a balance between the pressure applied to the back of the stamp and the deformation of the indenters. In general, it is believed that the advantages of the gap method are available if a gap exists over at least the majority of the surface area of the tool.

### Stamp Pulsing

Another group of inventions disclosed herein addresses a problem mentioned above regarding eliminating all of the resist at the locations of each protrusion, so that there is no remaining scum layer. As has been mentioned, by no remaining resist scum layer, it is meant no more than an amount that will not impede etching during a normal etching operation. These inventions include to repeatedly deform the indenting protrusions to clear the scum layer. These inventions are generally referred to as involving pulsing or tapping actions.

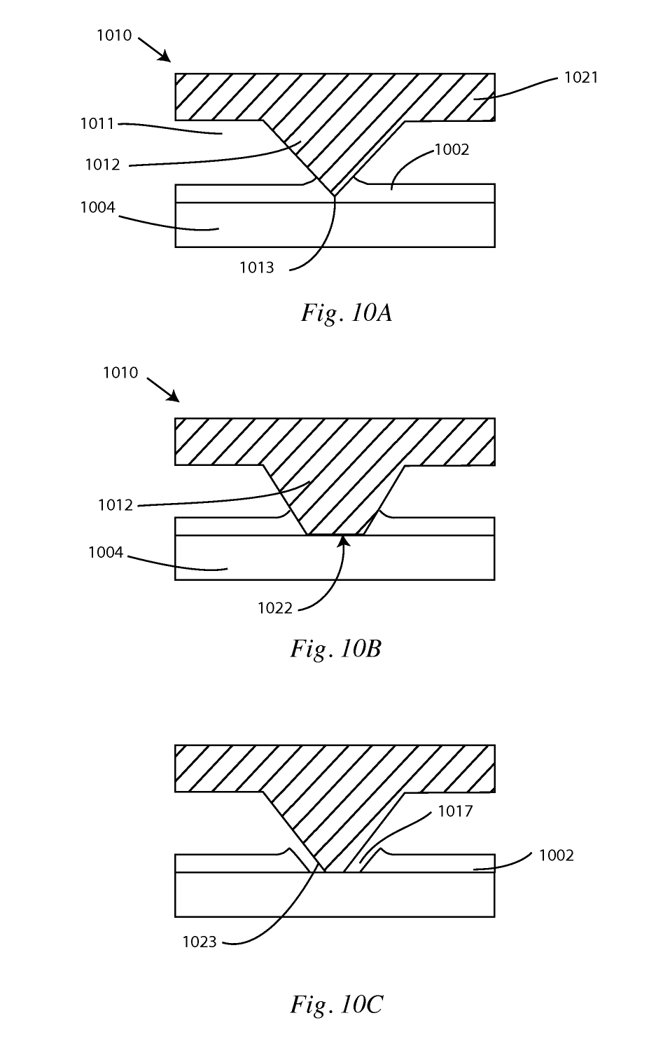

In one embodiment, as shown schematically with reference to FIGS. 10A, 10B and 10C, after an initial impression in the resist is made by applying pressure behind the stamp 1010 membrane, the pressure is reduced and then increased in several successive pulse cycles. Initially, before contact, the protrusion 1012 has a pointed tip 1013, which presses through the resist layer 1002 to contact the surface of the substrate wafer 1004. (It is not known if the tip of the protrusion absolutely contacts the substrate, or if, in fact, an extremely thin layer of resist material remains interposed between.) As pressure is increased, the stamp protrusion 1012 deforms, to a substantially flattened tip configuration 1022 as shown in FIG. 10B. As the protrusion deforms, it rolls and pushes resist 1002 away from locations directly under the deformed portions. Pressure is then reduced and the protrusion returns to its pointed shape. Pressure is then reapplied, and the protrusion again assumes the flattened tip configuration. This relaxation from a deformed state, and reapplication of pressure is repeated at least once, and optionally three or more (possibly many more) times during a pulsing mode.

Thus, as used herein, a pulsing cycle is considered to begin in a state where the protrusion is pressed against the substrate with a positive pressure and a generally flattened tip 1022. The pulse consists of the relaxation of pressure to a second, lower pressure, and then reapplication of pressure. During the pulsing, the pressure is not reduced to zero, but rather is reduced to a fraction of its maximum value. The reapplication of a heightened pressure can be back to pressure equal to that initially applied, before relaxation to the second, lower pressure, or to some other pressure. All that is required is that the return to an elevated pressure be to a pressure that is greater than the second, lower pressure.

For example, the pressure applied above the stamp can be typically in the range of about 0.25 to about 2 atm gauge pressure (that is the absolute pressure above the stamp is about 1.25-about 3 atm). Taking the case where the pressure applied above the stamp is about 0.5 atm gauge, a tapping cycle would consist of reducing this pressure to about 0.1 atm gauge and then increasing the pressure back up to about 0.5 atm gauge. A tapping cycle can take between about 0.1 and about 1 or 2 seconds, depending on how fast the equipment can remove and admit gas, and might possibly extend to as long as 10 seconds. It is believed that contact durations of as low as 0.1 seconds, and as long as 10 seconds may be useful. Operating the equipment at as high a frequency as is possible, minimizes the contact duration, and thus minimizes the excursion of resist material up along the face of the protrusion, as discussed above. The second, lower pressure may be within a range of about 0.1 atm gauge and about 1 atm gauge.

In this manner, the protrusion 1012 stays in contact with the substrate wafer 1004, that is, it does not lift entirely off from the substrate as the pressure behind the stamp is reduced. If several protrusions were to lift off, it would be unlikely that all protrusions would go back into their original openings upon successive pressure pulses. (It is not known how many protrusions can safely be allowed to lift off so that substantially all protrusions return to their original holes. However it is known that this is a condition to which to be sensitive.) The individual pyramidal protrusions 1012 do experience some spring-back as shown. (Although, in FIG. 10C, a space 1017 is shown between the side surfaces 1023 of the protrusion 1012 and the resist layer 1002, it is not known whether such a space actually comes into being, or whether the resist layer thins out adjacent the protrusion tip 1013, or some combination therebetween, as the protrusion is compressed and relaxed.)

The full pressure is then reapplied and as the pressure increases, it is believed that the flattening pyramid protrusion 1012 can push more of the resist 1002 out of the way. This cycle can be repeated a number of times. It has been found that three repetitions are sufficient to clear 98% of the holes for etching, but as few as one repeat or many more could be used. By clear, or uncover, it is generally meant, to reduce the amount of resist remaining at the location of the protrusion such that, upon etching with the standard etchant, for a reasonable length of time, at least the percent mentioned—98% of the locations corresponding to a protrusion, result in an acceptably etched hole in the substrate.

As has been mentioned, it should be noted that white light microscopic visual inspection is not sufficient to determine clearing, as some regions that appear visually to be clear of any scum layer do exhibit sufficient resistance to etching so that a hole is not sufficiently formed in the substrate.

Thus, it is not known for certain whether absolutely all of the resist layer is removed, as might be determined by some technique more sensitive than a white liquid microscope by even the pulsing action. What is known is that with pulsing, a higher percentage of holes in the resist, adequate for etching therethrough are produced. What is also known is that without pulsing, in some cases, a significant percentage of holes in the resist layer that appear to be clear of scum upon visual inspection, are not sufficiently clear to permit etching.

It should also be noted that upon the conclusion of a final pulse, pressure is retained, and then the temperature of the environment affecting the resist is reduced, such that it cools in place. Then, the pressure is reduced and the stamp is peeled away, leaving the hole in the solidified, or hardened resist.

At all times during the pulsing phase of this method, a gap 1011 remains open in the field of space between all of the protrusions 1012.

Rather than advancing the tool toward the substrate using pneumatic pressure, such as air or another fluid as generally described above, the tool can be advanced using a mechanical apparatus that forces the tool toward and against the substrate. This is so in connection with both the inventions related to pulsing the tool, and also those related to maintaining a gap adjacent the resist material.

This disclosure describes and discloses more than one invention. The inventions are set forth in the claims of this and related documents, not only as filed, but also as developed during prosecution of any patent application based on this disclosure. The inventor intends to claim all of the various inventions to the limits permitted by the prior art, as it is subsequently determined to be. No feature described herein is essential to each invention disclosed herein. Thus, the inventor intends that no features described herein, but not claimed in any particular claim of any patent based on this disclosure, should be incorporated into any such claim.

For instance, the inventions that relate to leaving a gap and solving the problems of insuring that resist adequately covers the entire area of the substrate during the wedging process, avoiding uncovering, before the imprinted pattern is made in the resist, are independent from the inventions that relate to sufficiently removing the resist from the areas of the substrate adjacent the protrusions, from which it is desired to remove the resist, so that etchant can remove the underlying substrate material. But also, the two methods of maintaining a gap and pulsing can be practiced together, with the same substrate. Or, either method alone can be practiced without the other.

Further, within each group, there are independent aspects of inventions that can be practiced alone or in combination. For instance, with gap-maintaining method, the degree to which the resist climbs up the protrusion can be controlled by altering any one or more of: the wetting angle of the material combination, or the viscosity of the resist material, the duration of contact time, the temperature (which affects viscosity) and the degree of compression. Viscosity may be adjusted by adjusting the components of the resist. The size and shape of the protrusions, and the inclination of their extended members may also be altered to adjust the degree to which resist travels along them.

Some assemblies of hardware, or groups of steps, are referred to herein as an invention. However, this is not an admission that any such assemblies or groups are necessarily patentably distinct inventions, particularly as contemplated by laws and regulations regarding the number of inventions that will be examined in one patent application, or unity of invention. It is intended to be a short way of saying an embodiment of an invention.

An abstract is submitted herewith. It is emphasized that this abstract is being provided to comply with the rule requiring an abstract that will allow examiners and other searchers to quickly ascertain the subject matter of the technical disclosure. It is submitted with the understanding that it will not be used to interpret or limit the scope or meaning of the claims, as promised by the Patent Office's rule.

The foregoing discussion should be understood as illustrative and should not be considered to be limiting in any sense. While the inventions have been particularly shown and described with references to preferred embodiments thereof, it will be understood by those skilled in the art that various changes in form and details may be made therein without departing from the spirit and scope of the inventions as defined by the claims.

The corresponding structures, materials, acts and equivalents of all means or step plus function elements in the claims below are intended to include any structure, material, or acts for performing the functions in combination with other claimed elements as specifically claimed.

### Aspects of Inventions

The following aspects of inventions hereof are intended to be described herein, and this section is to ensure that they are mentioned. They are styled as aspects, and although they appear similar to claims, they are not claims. However, at some point in the future, the applicants reserve the right to claim any and all of these aspects in this and any related applications.

1. A method of imparting a pattern of material a substrate, comprising the steps of:
a. providing a substrate and a stamp with patterned, deformable, spaced apart features, which protrude from an extended surface of the stamp, the protrusions have a length;
b. providing, in at least one region of the substrate, a material that becomes flowable upon heating to a flow temperature, the material being provided to a depth less than the feature length;
c. contacting the protruding features with the flowable material;
d. applying a first pressure to a side of the stamp opposite the protruding features, to a degree such that:
   i. the protruding features penetrate the flowable material;
   ii. upon contact with the substrate, the protruding features deform to an extent that a gap exists over a majority of the surface of the flowable material, between the flowable material and the extended surface of the stamp;
e. heating the flowable material to a temperature sufficient to allow the flowable material to flow; and
g. retracting the stamp to reveal patterned material covering regions of the substrate.

2. A method of imparting a pattern of material to a substrate, comprising the steps of:
a. providing a substrate and a stamp with, deformable, spaced apart features, which protrude from an extended surface of the stamp, the features have a length;
b. providing, in at least one region of the substrate, a material that becomes flowable upon heating to a flow temperature;
c. contacting the protruding features with the flowable material;
d. applying a first pressure to a side of the stamp opposite the protruding features, to a degree such that:
   i. the protruding features penetrate the flowable material; and
   ii. upon contact with the substrate, the protruding features deform; and
e. applying a second pressure that is less than the first pressure to a degree that the deformation of the protruding feature is reduced;
f. applying a pressure to the side of the stamp opposite the protruding features which pressure is greater than the second pressure;
g. before or during step f, heating the flowable material to a temperature sufficient to allow the flowable materials to flow; and
h. retracting the stamp to reveal patterned material covering regions of the substrate.

3. The method of any of aspects 1-2, further comprising the step of cooling the flowable material.

4. the method of aspects 3, the step of cooling being conducted so that the flowable material becomes unflowing.

5. The method of any of Aspects 1-4, the step of applying a first pressure comprising applying pressure such that a predetermined areal extent of the feature of the stamp being deformed elastically into intimate contact with the substrate.

6. The method of any of Aspects 1-5, which patterned material includes at least one region of substrate not covered by flowable material, which was previously covered with flowable material,

7. The method of aspect 6, the not covered region being not covered, as determined by an etching test.

8. The method of any of aspects 1-7, the not covered region corresponding to a protruding feature of the stamp.

9. The method of any of Aspects 1-8, the stamp having an elastic modulus of less than approximately 50 MPa, preferably between approximately 0.5 MPa and approximately 35 MPa, more preferably between about 2 MPa and 15 MPa.

10. The method of any of Aspects 1-9, further comprising subjecting the patterned substrate to a subsequent etching processing step.

11. The method of any of Aspects 1-10 the material that becomes flowable comprising a wax.

12. The method of any of Aspects 1-11, the material that becomes flowable comprising a resin.

13. The method of any of Aspects 1-12, the material that becomes flowable comprising a rosin.

14. The method of any of aspects 1-13, the material becoming flowable at a temperature of less than about 100° C.

15. The method of any of aspects 1-14, the material that becomes flowable having a viscosity of between about 5,000 and about 500,000 centipoise at the flow temperature and preferably between about 20,000 and about 200,000 centipoise.

16. The method of any of aspect 15, the material that becomes flowable having a viscosity within the specified range over a temperature range of at least about 2° C. and preferably of at least about 5° C.

17. The method of any of aspects 1-16, the material that becomes flowable comprising at least two components.

18. The method of any of aspects 1-17, the step of applying relative pressure to the stamp being conducted for a contact time of between about 0.5 and about ten seconds, preferably between about 1 and about 5 seconds.

19. The method of any of aspects 1-18, the protruding features having a length of between approximately 2 and approximately 20 microns, preferably about 10 microns.

20. The method of any of aspects 1-19, the step of providing material that becomes flowable comprising providing a material of a depth of less than about 5 microns.

21. The method of any of aspects 1-19, the step of providing material comprising providing a flowable material of a depth of between about 0.7 and about 5 microns, preferably less than about 3.5 microns.

22. The method of any of aspects 1-21, the protruding features comprising features having a base and a tip, where the tip is rounded and the feature has a substantially circular cross-section, which decreases in radius from the base to the tip.

23. The method of any of aspects 1-22, the protruding features comprising features having a base and a tip, where the tip has a sharp point in at least one aspect.

24. The method of any of aspects 1-23, the protruding features comprising features having a triangular cross section in at least one aspect.

25. The method of any of aspects 1-23, the protruding features having a trapezoidal cross section in at least one aspect.

26. The method of any of aspects 1-25, the stamp comprising pyramidal pointed protruding features.

27. The method of any of aspects 1-26, further comprising processing the substrate to form a photovoltaic cell.

28. The method of any of aspects 2-27, the steps (d) (e) and (f) defining as a pulse cycle, being conducted at a frequency of at least ½ pulse every second.

29. The method of any of aspects 1-28, the step of applying a first pressure comprising applying between about 0.25 to about 2 atm gauge pressure, and the step of applying a second pressure comprising applying a pressure between about 0.1 atm gauge and about 1 atm gauge.

30. The method of any of aspects 2-29, further comprising repeating the steps (e) and (f) at least two additional times.

31. The method of any of aspects 5-30, the depth of material that would result in no gap existing between the flowable material and the extended surface being called a Benchmark Unit depth of material, further, the step of providing material comprising providing material such that the gap over the majority of the surface has an extent of between 0.9 and 0.3 Benchmark Unit.

32. The method of any of aspects 5-30, the depth of material that would result in no gap existing between the flowable material and the extended surface being called a Benchmark Unit depth of material, further, the step of providing material comprising providing material over the majority of the surface to a depth of between 0.1 and 0.7 Benchmark Unit.

Having described the inventions disclosed herein,

What is claimed is:

1. A method of imparting a pattern of material to a substrate, comprising the steps of:
a. providing a substrate and a stamp with deformable, spaced apart features, which protrude from an extended surface of the stamp, the features having a length;
b. providing, in at least one region of the substrate, a material that becomes flowable upon heating to a flow temperature, the material being provided to a depth less than the feature length;
c. contacting the protruding features with the flowable material;
d. applying a first pressure to a side of the stamp opposite the protruding features to a degree such that:
i. the protruding features penetrate the flowable material; and
ii. upon contact with the substrate, the protruding features deform to an extent that a gap exists over a majority of the surface of the flowable material, between the flowable material and the extended surface of the stamp;
e. heating the flowable material to a temperature sufficient to allow the flowable materials to flow; and
f. retracting the stamp to reveal patterned material covering regions of the substrate.

2. (canceled)

3. The method of claim 1, further comprising the step of cooling the flowable material.

4. The method of claim 3, the step of cooling being conducted so that the flowable material becomes unflowing.

5. (canceled)

6. The method of claim 1, which patterned material includes at least one region of substrate not covered by flowable material, which was previously covered with flowable material.

7. The method of claim 6, the not covered region being not covered, as determined by an etching test.

8. The method of claim 6, the not covered region corresponding to a protruding feature of the stamp.

9. The method of claim 1, the stamp having an elastic modulus of less than approximately 50 MPa, preferably between approximately 0.5 MPa and approximately 35 MPa, and more preferably between about 2 MPa and 15 MPa.

10. The method of claim 1, further comprising subjecting the patterned substrate to a subsequent etching processing step.

11. The method of claim 1, the material that becomes flowable comprising a wax.

12. The method of claim 1, the material that becomes flowable comprising a resin.

13. The method of claim 1, the material that becomes flowable comprising a rosin.

14. The method of claim 1, the material becoming flowable at a temperature of less than about 100° C.

15. The method of claim 1, the material that becomes flowable having a viscosity of between about 5,000 and about 500,000 centipoise at the flow temperature and preferably between about 20,000 and about 200,000 centipoise.

16. The method of claim 15, the material that becomes flowable having a viscosity within the specified range over a temperature range of at least about 2° C. and preferably of at least about 5° C.

17. The method of claim 1, the material that becomes flowable comprising at least two components.

18. (canceled)

19. The method of claim 1, the protruding features having a length of between approximately 2 and approximately 20 microns, preferably about 10 microns.

20. The method of claim 1, the step of providing material that becomes flowable comprising providing a material of a depth of less than about 5 microns.

21. The method of claim 1, the step of providing material that becomes flowable comprising providing a material of a depth of between about 0.7 and about 5 microns, preferably less than about 3.5 microns.

22. The method of claim 1, the protruding features comprising features having a base and a tip, where the tip is rounded and the feature has a substantially circular cross-section, which decreases in diameter from the base to the tip.

23. The method of claim 1, the protruding features comprising features having a base and a tip, where the tip has a sharp point in at least one aspect.

24. The method of claim 1, the protruding features comprising features having a triangular cross section in at least one aspect.

25. The method of claim 1, the protruding features having a trapezoidal cross section in at least one aspect.

26. The method of claim 1, the stamp comprising pyramidal pointed protruding features.

27. The method of claim 1, further comprising processing the substrate to form a photovoltaic cell.

28. (canceled)

29. (canceled)

30. (canceled)

31. The method of claim 1, the depth of material that would result in no gap existing between the flowable material and the extended surface being called a Benchmark Unit depth of material, further, the step of providing material comprising providing material such that the gap over the majority of the surface has an extent of between 0.9 and 0.3 Benchmark Unit.

32. The method of claim 1, the depth of material that would result in no gap existing between the flowable material and the extended surface being called a Benchmark Unit depth of material, further, the step of providing material comprising providing material over the majority of the surface to a depth of between 0.1 and 0.7 Benchmark Unit.
